(19) United States
(12) Patent Application Publication
(10) Pub. No.: US 2010/0178614 A1
(43) Pub. Date: Jul. 15, 2010

(54) METHOD FOR MANUFACTURING A LENS

(76) Inventors: Chul Jin Hwang, Gyeonggi-do (KR); Young Moo Heo, Seoul (KR); Jeong Jin Kang, Seoul (KR); Jong Sun Kim, Gyeonggi-do (KR); Young Bae Ko, Seoul (KR)

Correspondence Address: KED & ASSOCIATES, LLP, P.O. Box 221200, Chantilly, VA, 20153-1200, US

(21) Appl. No.: 12/064,452

(22) PCT Filed: Aug. 31, 2005
(86) PCT No.: PCT/KR05/02886

§ 371 Date: Feb. 21, 2008

(51) Int. Cl. G03F 7/20

(52) U.S. Cl. 430/321

(57) ABSTRACT

In the present invention a mask (21) with a concentric pattern (a,b,c,d) is fabricated and aligned on a substrate (130) coated with a photoresist (131) and is then light-exposed. The light-exposed substrate is developed to obtain a concentric pattern of the photoresist in the form of tori. Then, a reflow process is performed for the developed substrate to allow the photoresist in the form of tori to be curved. A stamper in which the concentric pattern of the photoresist in thr form of tori is engraved in a depressed fashion is fabricated. Thereafter, by using the stamper as a mold, a lens and a lens array with the concentric pattern are formed.

### TECHNICAL FIELD

The present invention relates to a method of manufacturing a lens and a lens array, and more particularly, to a method of manufacturing a lens with a concentric pattern in which each torus forming the concentric pattern serves as a spherical lens, a multi-layered microlens in which lenses in the order of micrometers are formed on a lens in the order of several tens micrometers, and a microlens with a grating formed thereon.

### BACKGROUND ART

In general, a lens is processed to have an entire smooth surface and a negative or positive refractive index. In sane cases, a lens may be manufactured to have a particular pattern on its surface for special purposes, for example, to correct the path of a portion of light incident on the lens or make parallel light.

Among special-purposed lenses, a Fresnel lens with a concentric pattern as in the present invention is shown in FIG. 1. In FIG. 1, FIG. 1(a) is a perspective view of the Fresnel lens and FIG. 1(b) is a longitudinal sectional view of the Fresnel lens.

As shown in FIG. 1, the Fresnel lens is a condenser lens obtained by designing a convex leans into a flat form in order to reduce the thickness of a spherical lens and to simultaneously correct distortion in the spherical lens. That is, concentric bands with different diameters are formed around the center of the lens, and each band has a prism function, thereby reducing aberration in the lens. This Fresnel lens has been used for a lighthouse from old times. Recently, this lens has been made of a plastic material and applied to various fields such as a pint plate for brightening a view finder of a camera, an overhead projector, a tail lamp for a car, a light collimator, and the like.

At this time, a mechanical machining process has been used to manufacture a lens with a concentric pattern such as the Fresnel lens. Thus, in a case where a lens, particularly a microlens with a concentric pattern is manufactured through the conventional technique, there are many problems in that a great deal of time is required, production costs increase, and the mechanical machining process leads to degradation in precision and fails to provide a desired pattern.

In addition, a conventional microlens array is formed in such a manner that a plurality of hemispherical microlenses are arranged in a specific pattern. This microlens array is used mainly for a projection TV, a waveguide plate, and the like to condense or diverse a light path.

However, the microlens Ruining the conventional microlens array has many limitations on its curvature upon fabrication thereof, thus failing to manufacture a microlens with various optical characteristics.

### DISCLOSURE OF INVENTION

### Technical Problem

The present invention is conceived to solve the problems in the prior art. An object of the present invention is to provide a method of manufacturing a lens with a concentric pattern, wherein the desired pattern can be obtained, a manufacturing process can be simplified, and the precision of the lens can be improved.

To solve the problems, another object of the present invention is to provide a method of manufacturing a multi-layered microlens and a multi-layered microlens manufactured by the method, wherein microlenses in the order of micrometers are formed on a microlens in the order of several tens micrometers.

To solve the problem, a further object of the present invention is to provide a method of manufacturing a microlens, wherein a grating is formed on a microlens in the order of micrometers.

### Technical Solution

According to the present invention for achieving the objects, there is provided a method of manufacturing a lens with a concentric pattern, comprising a first step of fabricating a mask with the concentric pattern; a second step of aligning the mask on a substrate coated with a photoresist and performing a light-exposing process; a third step of developing the light-exposed substrate to obtain a concentric pattern formed of the photoresist in the form of tori; a fourth step of performing a reflow process for the developed substrate to allow the photoresist in the form of tori to be curved; a fifth step of fabricating a stamper in which the concentric pattern formed of the photoresist in the form of tori is engraved in a depressed fashion; and a sixth step of injection-molding a lens with the concentric pattern by using the stamper as a mold.

The mask preferably comprises a film mask or a chromium mask.

In addition, in the third step, AZ-series 400K is used as a developing solution, and the developing is performed in such a way as to dip for six minutes in the developing solution of 23° C.

The fifth step preferably comprises the steps of coating a metallic thin film on the substrate; electroplating the metallic thin film with nickel and separating a nickel-plated portion from the substrate; and using the nickel-plated portion as the stamper. In the fifth step, the coating of the metallic thin film preferably comprises chromium coating. Additionally, in the fifth step, gold is preferably further coated after coating the chromium.

According to the present invention for achieving the objects, there is provided a method of manufacturing a multi-layered microlens, comprising a first step of aligning a first mask, which includes a circular light-shielding region through which light cannot be transmitted, on a substrate coated with a photoresist and performing a light-exposing process; a second step of developing the light-exposed substrate to obtain a cylindrical photoresist portion; a third step of performing a reflow process for the developed substrate to change the photoresist portion into a spherical lens feature; a fourth step of fabricating a first stamper in which the spherical lens feature is engraved in a depressed fashion; a fifth step of fabricating a second stamper in which the spherical lens feature is formed in a raised fashion, by using the first stamper; a sixth step of aligning a second mask, which includes a light-shield region smaller than the circular light-shielding region formed in the first mask, on the second stamper coated with a photoresist and performing a light-exposing process; a seventh step of developing the photoresist formed on the spherical lens of the second stamper through the light exposure and performing a reflow process; an eighth step of fabricating a third stamp in which a double-layered structure composed of the photoresist formed on the spherical lens is engraved in a depressed fashion; and a ninth step of injection-molding a lens by using the third stamper as a mold so that the double-layered structure composed of the photoresist formed on the spherical lens is formed thereon in a raised fashion.

According to the present invention for achieving the objects, there is provided a method of manufacturing a microlens with a grating formed thereon, comprising a first step of aligning a first mask, which includes a circular light-shielding region through which light cannot be transmitted, on a substrate coated with a photoresist and performing a light-exposing process; a second step of developing the light-exposed substrate to obtain a cylindrical photoresist portion; a third step of performing a reflow process for the developed substrate to change the photoresist into a spherical lens feature; a fourth step of fabricating a first stamper in which the spherical lens feature is engraved in a depressed fashion; a fifth step of fabricating a second stamper that is made of a transparent plastic material and formed with the spherical lens feature in a raised fashion by using the first stamper as a mold; a sixth step of coating a metal on the second stamper and coating the grating material with a photoresist; a seventh step of aligning a second mask, which includes a light-shield region with a grating feature smaller than the light-shielding region formed on the first mask, on the second stamper coated with the photoresist and performing a light-exposing process; and an eighth step of developing the photoresist formed on the spherical lens of the second stamper through the light exposure and etching the thin film, thereby forming the grating feature on the spherical lens.

### Advantageous Effects

According to the present invention, there is an advantage in that a lens is manufactured using a semiconductor fabricating process so that a lens in the order of micrometers can be fabricated with improved precision. In addition, there is an advantage in that the present invention provides a multi-layered microlens and a microlens array in various forms.

The present invention has advantages in that it can be applied to a light guiding plate and various other optical parts and diffractive optical elements to control a light path, a manufacturing process can be simplified, and production costs can be reduced.

### BRIEF DESCRIPTION OF THE DRAWINGS

FIG. 1 shows a perspective view and a longitudinal sectional view of a general Fresnel lens.

FIG. 2 is a front view of a mask with a concentric pattern formed thereon according to an embodiment of the present invention.

FIGS. 3 to 6 are views illustrating a process of forming a concentric pattern on a substrate using the mask.

FIGS. 7 to 9 are views illustrating a process of forming a stamper using the concentric circle-shaped lens structure manufactured above.

FIG. 10 is a view showing the configuration of a lens with a concentric pattern manufactured according to the present invention.

FIG. 11 shows the cross-sectional view of the entire concentric pattern in the lens of FIG. 10.

FIG. 12 shows an example in which the lens with the concentric pattern according to the present invention is applied to a light guiding plate.

FIG. 13 is a perspective view showing a conventional microlens array.

FIG. 14 is a perspective view of a mask for use in the present invention.

FIGS. 15 to 18 are views illustrating a process of fouling spherical lens features on a substrate according to an embodiment of the present invention.

FIGS. 19 to 21 are views illustrating a process of forming a stamper with spherical lens features according to an embodiment of the present invention.

FIG. 22 is a perspective view of a stamper with spherical lens features are formed in a raised fashion according to an embodiment of the present invention.

FIGS. 23 to 25 are views illustrating a process of forming microlenses on spherical lenses of the stamper according to an embodiment of the present invention.

FIG. 26 is a perspective view of a double-layered microlens in which concentric lenses are formed on spherical lenses according to an embodiment of the present invention.

FIG. 27 is a perspective view of a double-layered microlens in which cylindrical lenses are formed on spherical lenses according to an embodiment of the present invention.

FIG. 28 is a perspective view of a double-layered microlens in which intercrossing cylindrical lenses are formed on spherical lenses according to an embodiment of the present invention.

FIG. 29 is a perspective view of a double-layered microlens in which a plurality of spherical lenses are formed on each of spherical lenses according to an embodiment of the present invention.

FIG. 30 is a perspective view showing an example in which a double-layered microlens according to an embodiment of the present invention is applied to a light guiding plate.

FIG. 31 is a perspective view showing a conventional microlens array.

FIG. 32 is a perspective view of a mask for use in the present invention.

FIGS. 33 to 36 are views illustrating a process of forming spherical lens features on a substrate according to an embodiment of the present invention.

FIGS. 37 to 39 are views illustrating a process of manufacturing a stamper with spherical lens features according to an embodiment of the present invention.

FIG. 40 is a perspective view of a stamper in which spherical lens features are formed in a raised fashion according to an embodiment of the present invention.

FIGS. 41 to 45 are views illustrating a process of forming a grating on the spherical lens of a stamper according to an embodiment of the present invention.

FIG. 46 is a perspective view of a microlens array in which a concentric grating is formed on the spherical lens according to an embodiment of the present invention.

FIG. 47 is a perspective view of a microlens array in which a grating is formed on a spherical lens in a raised and depressed fashion according to an embodiment of the present invention.

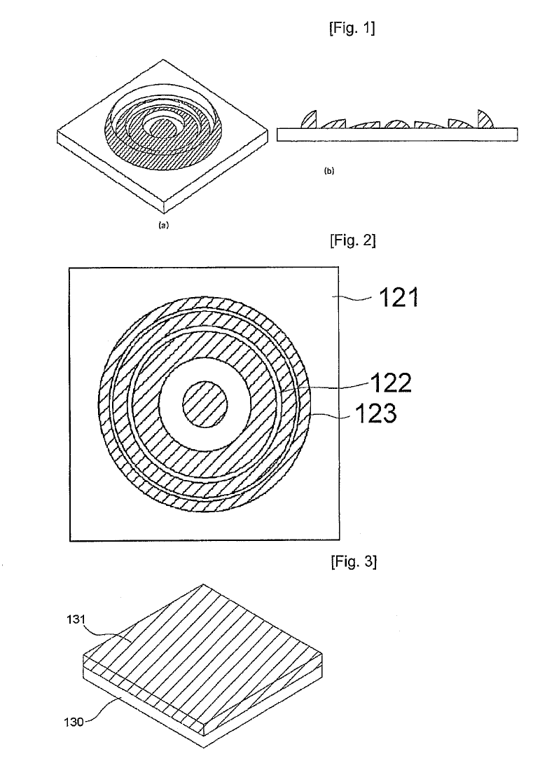

### BEST MODE FOR CARRYING OUT THE INVENTION

Hereinafter, preferred embodiments of the present invention will be described with reference to the accompanying drawings. In the following description, details on specific techniques for known functions and constitutions may be mined to avoid unnecessarily obscuring the subject manner of the present invention. The terms used herein are terms defined in consideration of functions in the present invention and may vary according to intentions or practices of users or operators. Thus, the definitions of the terms should be determined on the basis of the description throughout the specification.

In the present invention, a mask 121 for forming a concentric pattern is first fabricated. FIG. 2 shows an example of the mask for fouling the concentric pattern of the present invention.

As illustrated in FIG. 2, the mask 121 includes light-transmissive portions 122 and light non-transmissive portions 123. When the mask 121 is fabricated by a manufacturer, the shape and pattern of the light non-transmissive portions 123 are determined according to the configuration of a lens to be manufactured. Since a microlens in the form of a spherical lens should be first manufactured in the present invention, the light non-transmissive portions 123 are formed in the form of concentric circles. In addition, the thickness of each torus constituting the concentric pattern formed in the mask 121 is made to be different from one another.

Here, the mask 121 is determined as to whether it is formed of a film mask or a chromium mask, depending upon the precision of the pattern. In case of the use of a chromium mask, the pattern can be made with a precision in the order of 1 mn.

Meanwhile, as illustrated in FIG. 3, a photoresist (PR) 131 is coated on a glass or silicone wafer substrate 130 using a spin coater. Here, the type of the photoresist 131 to be used may be determined differently according to the thickness thereof. If a thick PR such as AZ-series 9260 is used, the coated PR has a thickness of 10 mm.

After coating, the coated substrate 130 is subjected to soft baking in an oven. At this time, baking conditions are preferably 30 minutes at 145° C.

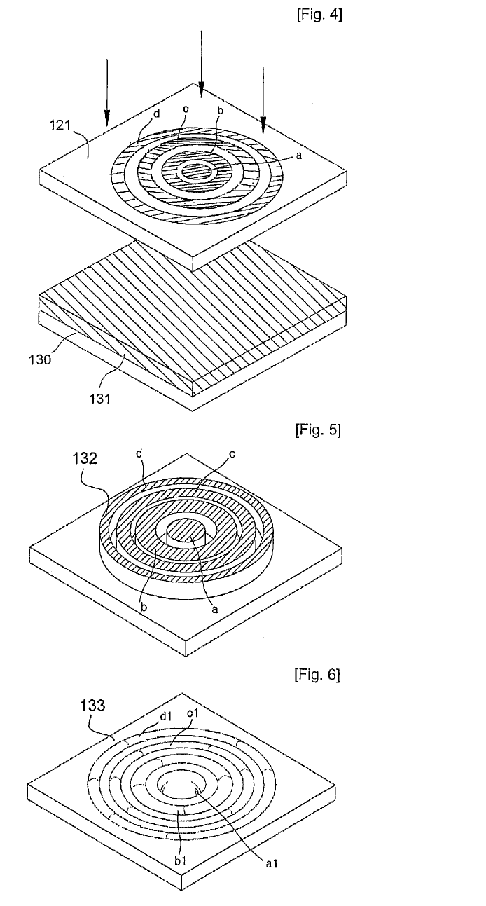

When the soft baking has been completed, as shown in FIG. 4, the mask 121 is aligned on the PR-coated substrate 130 using an alignment key. A light-exposing process is performed for a predetermined period of time. At this time, in the concentric pattern of the mask 121, each torus a, b, c and d has a different thickness, as illustrated in FIG. 4. That is, the center circle a has the largest thickness, and the thickness of the torus gradually decreases toward the outermost circle d that has the smallest thickness.

When the light-exposing process has been completed, a developing process is carried out. At this time, the type of developing solution is AZ-series 400K, and developing conditions are dipping in the developing solution at 23° C. for 6 minutes. As shown in FIG. 5, when the developing process has been performed, PR portions that have been exposed to light passing through the mask 121 are dissolved and other portions 132 that have not been exposed to the light remain as they are. That is, the torus structures with hollow cylindrical shapes are formed while maintaining the concentric pattern. At this time, the respective tori of the portions 132 that have not been exposed to the light have the same thicknesses and shapes as the corresponding tori of the concentric pattern in the mask. Thus, for the sake of easy explanation of the present invention, the tori in the mask and the tori obtained after light exposure are designated by the same reference numerals. Consequently, the respective tori a, b, and d obtained through the light exposure have thicknesses of which values are in the order of a>b>c>d.

After the developing process has been completed, a reflow process is performed using a hot plate apparatus so as to form a concentric-patterned PR 133 where each torus has a curved surface as shown in FIG. 6. The reflow process is a process of heating the PR 133 with the torus structure so that the photoresist (PR) can be heated and then melted down. At this time, reflow conditions may vary according to desired shapes, for example, for several minutes at 100 to 200° C.

As described above, the reflow process is performed for the tori a, b, c and d made of the photoresist shown in FIG. 5, and the curved tori a1, b1, c1 and d1 are formed. The spacing among the tori a1, b1, c1 and d1 becomes smaller than that among the tori a, b, c and d. This is because the PR 133 constituting the tori flows down to neighboring PR during the reflow process. If time for the reflow process is extended or the spacing between the adjacent tori is narrowed, the resultant shape of the PR obtained by the reflow process has a curved surface but the neighboring PR is in contact with each other, as shown in FIG. 10.

Here, due to the reflow process, the heights of the tori a, b, c and d shown in FIG. 5 are also changed in addition to the changes in the spacing among the tori. The changes in the heights of the tori height vary according to initial thicknesses of the tori prior to the reflow process. For example, through the reflow process, the tori a, b, c and d are changed into the tori a1, b1, c1 and d1 with heights of which values are in the order of a1>b1>c1>d1 (refer to FIG. 11).

As described above, since the curved shape and height of the PR can be adjusted through the reflow process, the present invention can design and determine the ratio of the heights of tori to provide microlenses and microlens arrays in various forms and patterns.

FIG. 7 shows a longitudinal sectional view of the substrate 130 after the reflow process. FIG. 7 shows a case where the spherical lens features are spaced apart from one another at predetermined intervals. As shown in FIG. 7, it can be seen that the curved torus 133 is changed into a microlens with a longitudinal section in the form of a spherical lens.

After the PR forming each torus is made in the form of a microlens, a metallic thin film 141 is coated on the substrate 130, as shown in FIG. 7. At this time, the coating of the metallic thin film 141 is typically chromium coating, and gold may be additionally coated.

After coating the metallic thin film, the substrate 130 is placed on a plating apparatus and then plated with nickel through an electroplating process, as shown in FIG. 8. At this time, a supplied electric current is a few amperes depending on each step. The plating thickness is 400 to 450 mm (on the basis of a 4-inch wafer), and a nickel-plated portion constitutes a stamper 142.

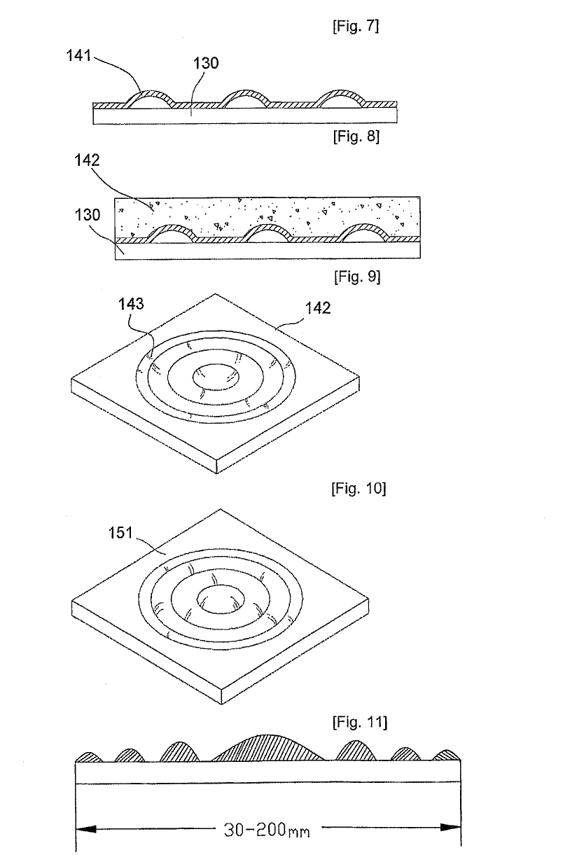

After the above nickel electroplating, the substrate 130 and the stamper 142 are separated from each other. At this time, the separated stamper 142 has the configuration shown in FIG. 9 if there is no spacing between the spherical lens features. If there is spacing between the spherical lens features, the stamper 142 has a configuration different from that shown in FIG. 9 in that the tori are spaced apart from one another. In addition, the stamper 142 has a configuration in which the PR constituting the concentric pattern 143 has been subjected to transfer so as to have an engraved pattern. That is, the concentric pattern is engraved in the stamper 142 in an intagliated fashion.

In the present invention, the stamper where the concentric pattern is engraved is used as a mold. Using the mold, an injection-molded flat lens 151 is obtained, as shown in FIG. 10. (The lens of FIG. 10 corresponds to a case where neighboring tori are in contact with each other.) The flat lens 151 is preferably formed of a transparent plastic material. In the flat lens 151, the diameter of the concentric lens (i.e., the pattern) is about 30 to 200 mm, as shown in FIG. 11. Referring to FIG. 11, the respective tori have different heights due to differences in their thicknesses. In this way, the present invention enables a microlens with a diameter of about 30 to 200 mm to have patterns with different heights and widths.

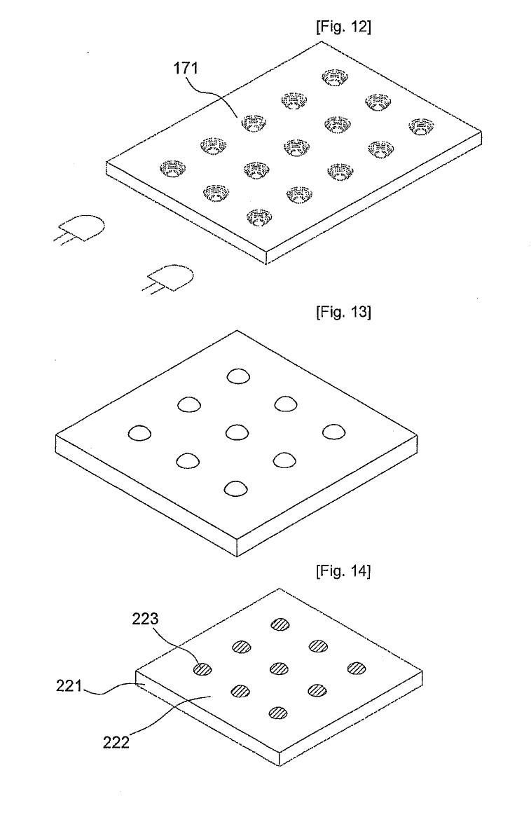

FIG. 12 shows an example in which the lens with the concentric pattern according to the present invention is applied to a light guiding plate 171. The light guiding plate is one of components used in an LCD backlight and can employ the flat lens 151 with the concentric pattern of the present invention, thereby controlling a light path.

In another embodiment of the present invention, a spherical lens in the order of several tens micrometers is first formed, and various lens structures in the order of micrometers are then formed on the spherical lens in the order of several tens micrometers.

Hereinafter, a first process of manufacturing a spherical lens in the order of several tens micrometers will be explained.

First, considering the area of the bottom of the spherical lens, a mask 221 is formed as shown in FIG. 14. FIG. 14 is a perspective view of the mask used in the present invention. The area and height of the spherical lens are related to the bottom area thereof and the height of a photoresist to be coated.

Upon manufacture of a mask, a mask for a single microlens may be fabricated according to the present invention. However, since microlenses are generally used in an array fowl, a microlens array is formed upon manufacture of the mask. It will be apparent to those skilled in the art that a single microlens can be easily manufactured through the process of manufacturing the microlens array of the present invention. Thus, details on a method of manufacturing a single microlens will be omitted herein.

Referring to FIG. 14, a mask 221 includes a major light-transmissive portion 222 and light non-transmissive portions 223. The light non-transmissive portions 223 are arranged in a specific pattern to be in the form of an array and take the shape of a circle.

Here, the mask is determined as to whether it is formed of a film mask or a chromium mask, depending upon the precision of the pattern. In case of the use of a chromium mask, the pattern can be made with a precision in the order of 1 nm.

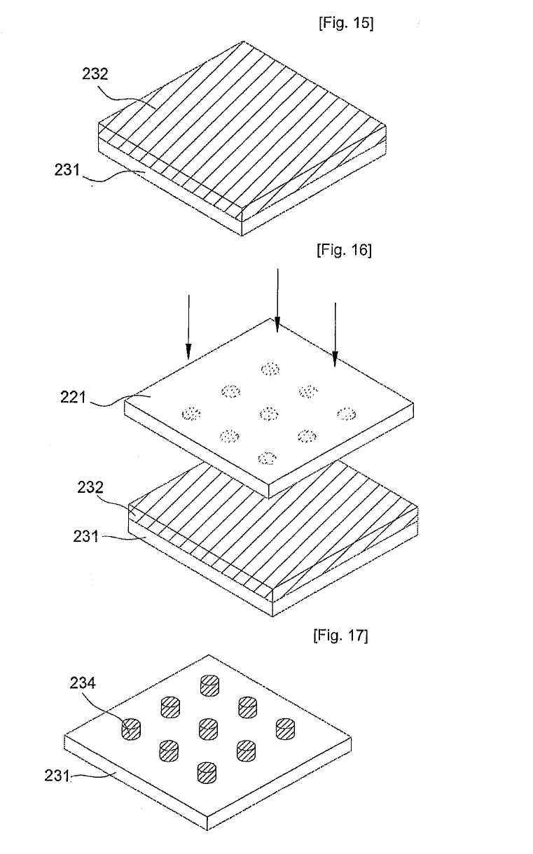

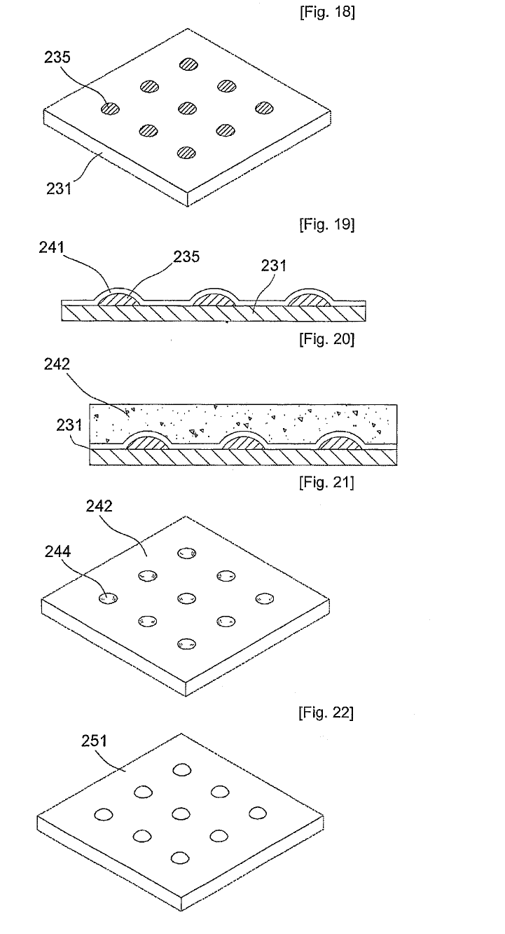

Meanwhile, as illustrated in FIG. 15, a photoresist (PR) 232 is coated on a glass or silicone wafer substrate 231 using a spin coater. Here, the type of the PR 232 to be used may be determined differently according to the thickness thereof. If a thick PR such as AZ-series 9260 is used, the coated PR has a thickness of 10 mm.

After coating, the coated substrate 231 is subjected to soft baking in an oven. At this time, baking conditions are preferably about 30 minutes at 145° C.

When the soft baking has been completed, as shown in FIG. 16, the mask 221 is aligned on the PR-coated substrate 231 using an alignment key. A light-exposing process is performed for a predetermined period of time.

When the light-exposing process has been completed, a developing process is carried out. At this time, the type of developing solution is AZ-series 400K, and developing conditions are dipping in the developing solution at 23° C. for 6 minutes. As shown in FIG. 17, when the developing process has been performed, PR portions that have been exposed to light passing through the mask 221 are dissolved and other portions that have not been exposed to the light remain as they are. Consequently, only the PR portions that have not been exposed to the light remain on the substrate 231. Since the light non-transmissive portions formed in the mask 221 has circular shapes, the PR portions 234 are in the form of cylinders.

After the developing process has been completed, a reflow process is performed using a hot plate apparatus so as to cause the PR portions 234 to be curved and to be formed into spherical lens features 235 as shown in the sectional view of FIG. 19. The reflow process is a process of heating the PR portions 234 so that the photoresist (PR) can be heated and then melted down. At this time, reflow conditions may vary according to desired shapes to be manufactured, for example, for several minutes at 100 to 200° C.

FIG. 19 shows a longitudinal sectional view of the substrate 231 after the reflow process. As shown in FIG. 19, it can be seen that the curved PR portions 234 are changed into microlenses 235 with a longitudinal section in the form of a spherical lens.

After the PR portions are formed into microlenses through the reflow process, a metallic thin film 241 is coated on the substrate 231, as shown in FIG. 19. At this time, the coating of the metallic thin film 241 is typically chromium (Cr) coating, and gold (Au) may be additionally coated.

After coating the metallic thin film, the substrate 231 is placed on a plating apparatus and then plated with nickel through an electroplating process as shown in FIG. 20. At this time, a supplied electric current is a few amperes depending on each step. The plating thickness is 400 to 450 nm (on the basis of a 4-inch wafer), and a nickel-plated portion constitutes a stamper 242.

After the above nickel electroplating, the substrate 231 and the stamper 242 are separated from each other. At this time, the separated stamper 242 has a pattern in which the spherical lens array has been engraved through transfer. That is, the engraved pattern 244 in the form of a spherical lens array is formed in the stamper 242.

When the stamper 242 in which the array of spherical lens features has been engraved is manufactured as described above, the stamper 242 is further plated with nickel again and the newly nickel-plated portion is separated from the stamper 242. The newly nickel-plated portion that has been separated from the stamper 242 becomes a stamper 251 with an array of raised spherical lens features corresponding to the engraved pattern of the stamper 242, as shown in FIG. 22.

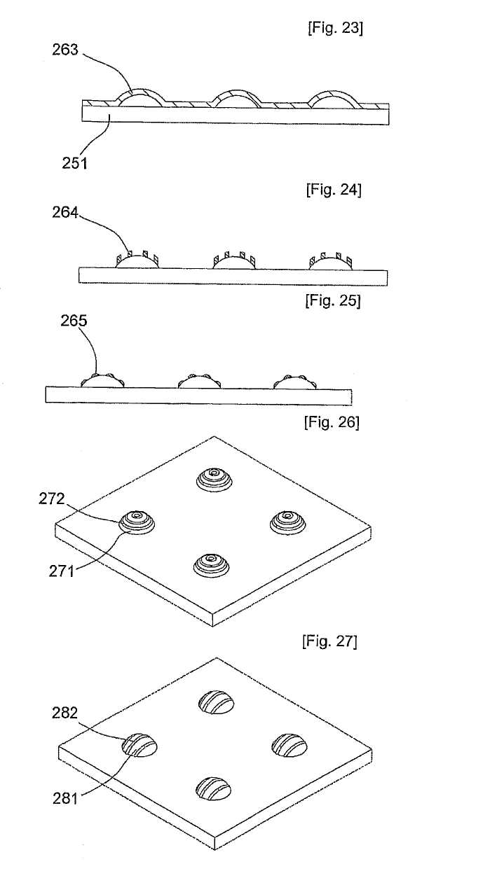

When the stamper 251 with the raised pattern has been manufactured, a photoresist (PR) 263 is coated on the stamper 251, as shown in FIG. 23. Thereafter, a mask for a double layer is aligned on the stamper 251 such as in FIG. 16, and light-exposing and developing processes are performed to form PR cylinders 264 on each of the spherical lenses, as shown in FIG. 24. The mask for a double layer is preferably a chromium mask.

After the PR cylinders 264 have been formed, a reflow process is carried out again so that the PR cylinders 264 can be changed into spherical lenses 265 with curved surfaces, as shown in FIG. 25. Here, if the spacing between the patterns in the mask is reduced or the reflow processing time is extended, the spherical lenses 265 arranged at predetermined intervals shown in FIG. 25 may be in contact with one another while the spacing between the spherical lenses is eliminated. That is, an embossed configuration is obtained.

As shown in FIG. 25, in order to manufacture a mold using the stamper 251 with double-layered microlenses due to the PR cylinders 264, a metallic thin film is coated and nickel is electroplated, as explained in connection with FIGS. 19 and 20. When nickel is electroplated, as shown in FIG. 21, the nickel-plated portion becomes a stamper in which a double-layered microlens array is engraved in a depressed fashion.

In the present invention, the stamper in which the double-layered microlens array is engraved in a depressed fashion is used as a mold. Using the mold, a double-layered microlens array is injection-molded in a raised fashion, as shown in FIG. 29. At this time, the double-layered microlens array is preferably formed of a transparent plastic material.

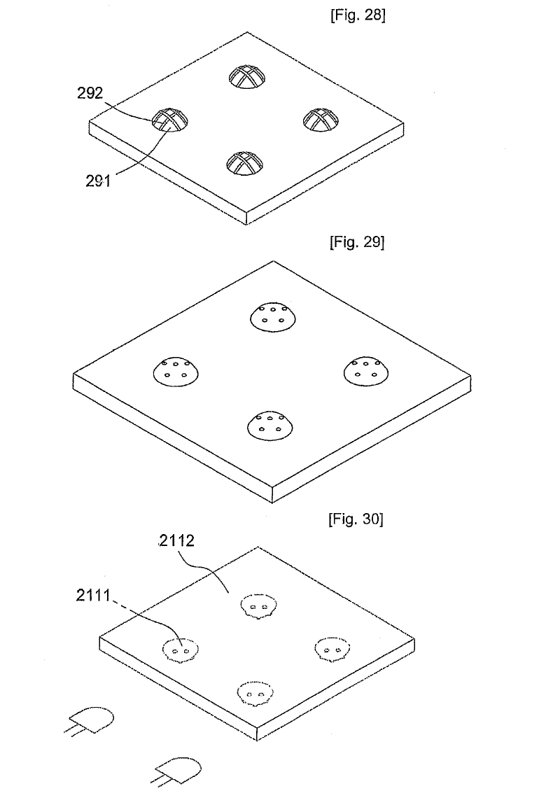

Here, after a microlens array is first formed as shown in FIG. 22, lens features that are to be formed on each spherical lens 271 of the microlens array may be formed in a concentric pattern 271 serving as a Fresnel lens as shown in FIG. 26, rather than spherical lens features shown in FIG. 25. In addition, as shown in FIG. 27, cylindrical lenses 282 with certain directionality may be formed on a spherical lens 281. Alternatively, as shown in FIG. 28, cylindrical lenses that intersect each other may be formed on a spherical lens 291, which is a modified version of the structure of FIG. 27.

As described above, various types of lenses can be formed on a spherical lens in such a manner that a pattern on the mask used in FIG. 24, i.e., light non-transmissive portions, are fabricated to conform to the shapes of lenses to be formed on the spherical lens.

In the lens structure of the present invention, the primary lens has a size of about 30 to 200 micrometers and the secondary lens has a size of about 1 to 10 micrometers.

FIG. 30 shows an example in which the double-layered microlens of the present invention is applied. FIG. 30 is a view showing an example in which the double-layered microlens of the present invention is applied to a light guiding plate 2112. The light guiding plate 2112 is one of components used in an LCD backlight and can employ the double-layered microlens of the present invention, thereby controlling a light path.

In another embodiment of the present invention, a spherical lens in the order of micrometers is first formed and a grating is then formed on the spherical lens.

Hereinafter, a first process of manufacturing a spherical lens in the order of micrometers will be explained.

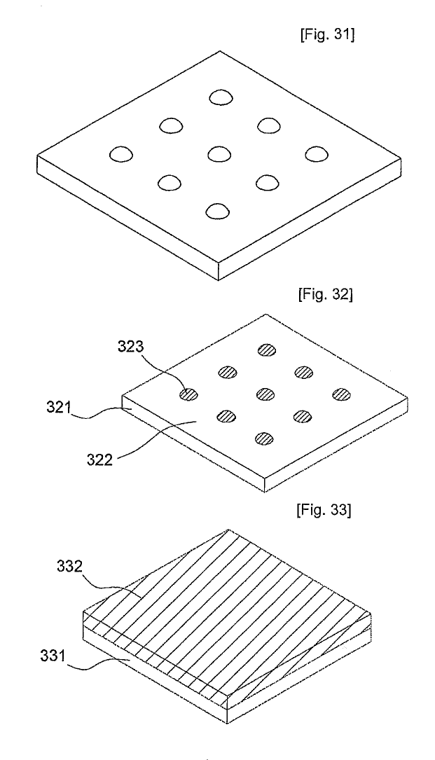

First, considering the area of the bottom of the spherical lens, a mask 321 is formed as shown in FIG. 32. The area and height of the spherical lens are related to the bottom area thereof and the height of a photoresist to be coated.

Upon manufacture of a mask, a mask for a single microlens may be fabricated according to the present invention. However, since microlenses are generally used in an array form, a microlens array is formed upon manufacture of the mask. It will be apparent to those skilled in the art that a single microlens can be easily manufactured through the process of manufacturing the microlens array of the present invention. Thus, details on a method of manufacturing a single microlens will be emitted herein.

Referring to FIG. 32, a mask 321 includes a light-transmissive portion 322 and light non-transmissive portions 323. The light non-transmissive portions 323 are arranged in a specific pattern to be in the form of an array and take the shape of a circle.

Here, the mask is determined as to whether it is formed of a film mask or a chromium mask, depending upon the precision of the pattern. In case of the use of a chromium mask, the pattern can be made with a precision in the order of 1 mm

Meanwhile, as illustrated in FIG. 33, a photoresist (PR) 332 is coated on a glass or silicone wafer substrate 331 using a spin coater. Here, the type of the PR 332 to be used may be determined differently according to the thickness thereof. If a thick PR such as AZ-series 9260 is used, the coated PR has a thickness of 10 min.

After coating, the coated substrate 331 is subjected to soft baking in an oven. At this time, baking conditions are preferably about 30 minutes at 145 C.

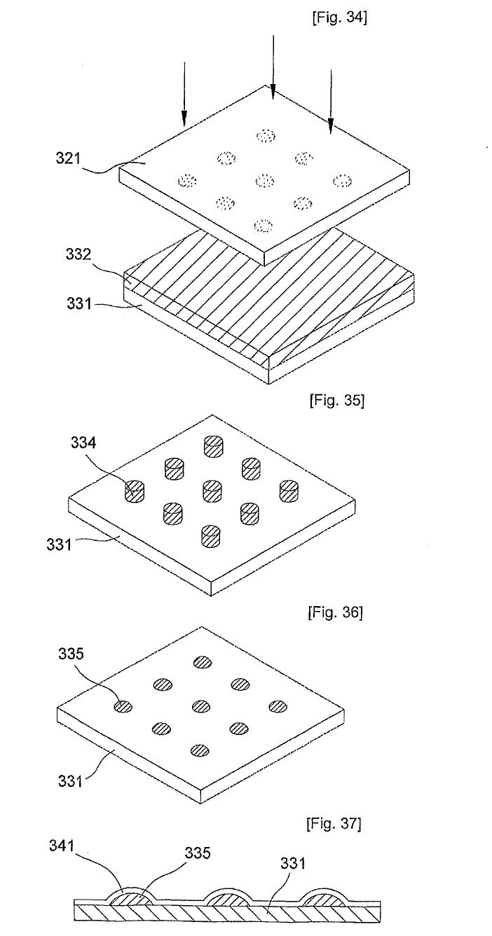

When the soft baking has been completed, as shown in FIG. 34, the mask 321 is aligned on the PR-coated substrate 331 using an alignment key. A light-exposing process is performed for a predetermined period of time.

When the light-exposing process has been completed, a developing process is carried out. At this time, the type of developing solution is AZ-series 400K, and developing conditions are dipping in the developing solution at 23 C for 6 minutes. As shown in FIG. 35, when the developing process has been performed, PR portions that have been exposed to light passing through the mask 321 are dissolved and other portions that have not been exposed to the light remain as they are. Consequently, only the PR portions that have not been exposed to the light remain on the substrate 331. Since the light non-transmissive portions formed in the mask 321 has circular shapes, the PR portions 334 are in the form of cylinders.

After the developing process has been completed, a reflow process is performed using a hot plate apparatus. Through the reflow process, the cylindrical PR portions 334 are curved and formed into spherical lens features 335 as shown in FIG. 36. Consequently, the substrate 331 has a configuration in which the plurality of PR portions 334 in the form of spherical lenses are arrayed. The reflow process is a process of heating the PR portions 334 so that the photoresist (PR) can be heated and then melted down. At this time, reflow conditions may vary according to desired shapes to be manufactured, for example, for several minutes at 100 to 200° C.

FIG. 37 shows a longitudinal sectional view of the substrate 331 after the reflow process. As shown in FIG. 37, it can be seen that the curved PR portions 334 are changed into the spherical lens features 335 in longitudinal section through the reflow process.

After the PR portions are formed into spherical lenses (i.e., microlenses) through the reflow process, a metallic thin film 341 is coated on the substrate 331, as shown in

FIG. 37. At this time, the coating of the metallic thin film 341 is typically chromium (Cr) coating, and gold (Au) may be additionally coated.

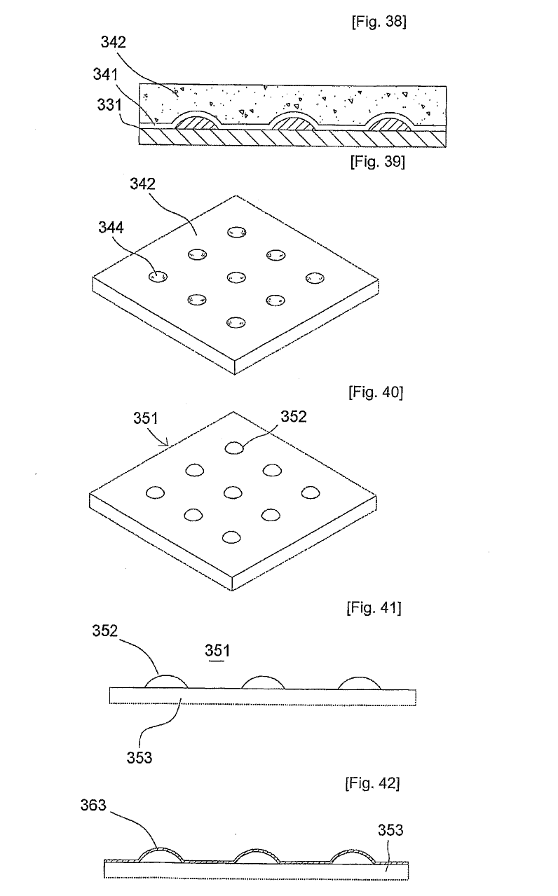

After coating the metallic thin film, the substrate 331 is placed on a plating apparatus and then plated with nickel through an electroplating process as shown in FIG. 38. At this time, a supplied electric current is a few amperes depending on each step. The plating thickness is 400 to 450 nm (on the basis of a 4-inch wafer), and a nickel-plated portion constitutes a stamper 342.

After the above nickel electroplating, the substrate 331 and the stamper 342 are separated from each other. At this time, the separated stamper 342 has a pattern as shown in FIG. 39. When the stamper 342 is separated from the substrate 331 as shown in FIG. 39, the separated stamper 342 has a pattern 344 in which a spherical lens array is engraved in a depressed fashion. That is, the pattern of the spherical lens array is engraved in the stamper 342 in a depressed fashion.

As described above, the stamper 342 in which the spherical lens array is engraved in a depressed fashion is nickel-plated again and the newly nickel-plated portion is then subjected to stampering by the stamper 342. The newly nickel-plated portion that has been separated from the stamper 342 becomes a stamper 351 with an array of spherical lens features 352 in a raised fashion, which corresponds to the depressed pattern of the stamper 342, as illustrated in FIG. 40.

Consequently, when the stamper 342 in which the array of the spherical lens features has been engraved in a depressed fashion is used as a mold and a transparent plastic material is injection-molded by means of the stamper 342, it is possible to manufacture a microlens array that is made of a transparent plastic material and has the same pattern as the stamper 351. After the microlens array made of the transparent plastic material has been manufactured, a grating is formed on each of microlenses constituting the microlens array.

Here, the grating is formed by forming light-transmissive portions and light non-transmissive portions on the lens structure. Thus, in order to form the light non-transmissive portions, a metallic grating is formed.

Hereinafter, a process of forming a metallic grating on a transparent plastic microlens, which has been injection-molded by using the stamper 342 as a mold, through a semiconductor process will be explained. Slice the transparent plastic microlens array corresponds to the stamper 351, like reference numerals are used.

When the transparent plastic microlens array 351 is manufactured as described above, as shown in FIG. 42, a metal 363 is coated on a plastic plate 353 for the microlens array 351 as shown in FIG. 41.

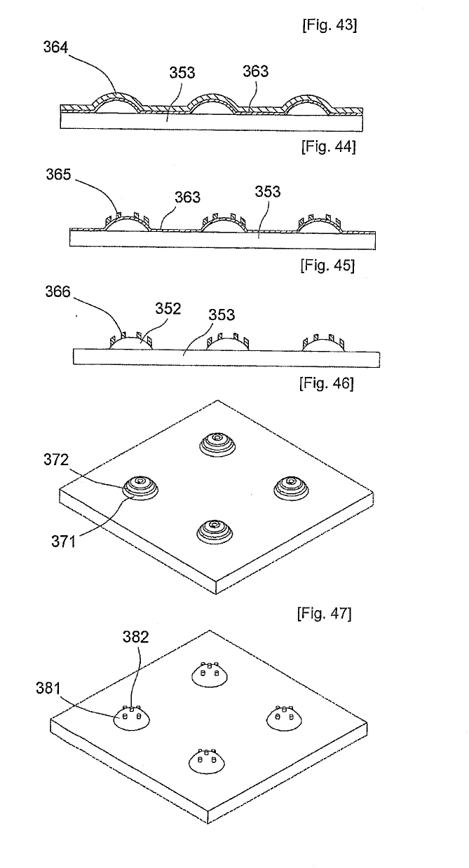

Thereafter, for light exposure using a mask, a photoresist (PR) 364 is coated on the coated metal 363 as shown in FIG. 43. Then, a grating mask for use in fouling a grating pattern is aligned on the stamper 351 and light-exposing and developing processes are performed, thereby forming cylindrical PR portions 365 on each of spherical lenses, as shown in FIG. 44. The grating mask is preferably a chromium mask.

Then, the coated metal 363 is etched along the cylindrical PR portions 365 and the remaining PR portion is removed, thereby forming a grating 366 made of the metal 363, as shown in FIG. 45. FIG. 46 shows an example of a microlens array with the grating formed thereon as described above. Referring to FIG. 46, a grating with a concentric pattern 372 is formed on a spherical lens 371.

Meanwhile, during performing the above process, a material with a different refractive index may be coated instead of a metal to manufacture a microlens array with grating effects resulting from an interference phenomenon. That is, a transparent thin film made of an oxide such as SiO₂ or a nitride such as Si₃N₄ is coated on the microlens array, and then etched to form a grating structure that has a different refractive index. A typical oxide thin film and the like have a refractive index of 2 to 3, and a plastic material such as PMMA has a refractive index of 4 or higher. Thus, grating effects can be obtained from interference due to the difference in the refractive indices of the two materials.

Alternatively, protrusions may be formed on a microlens feature array in a stamper and an injection-molding process may be carried out, thereby manufacturing a lens structure in which protrusions 382 are formed on a plastic microlens array 381, as shown in FIG. 47. When the lens structure with the protrusions 382 is formed on the microlens, there are differences in light paths at the microlens and the protrusions, thereby exhibiting grating effects caused by a light interference phenomenon. In this lens structure, the primary lens has a size of about 30 to 200 micrometers and the grating has a size of a few micrometers.

The grating lens structure of the protrusions 382 shown in FIG. 47 can be applied to a light guiding plate. The light guiding plate is one of components used in an LCD backlight and can employ the grating lens structure to control a light path.

Although the technical spirit of the present invention has been described with reference to the accompanying drawings, the description does not limit the present invention but merely explains the preferred embodiments of the present invention.

Further, it will be understood by those skilled in the art that various changes and modifications can be made thereto without departing from the technical spirit and scope of the present invention.

1. A method of manufacturing a lens with a concentric pattern, the method comprising:
a first step of fabricating a mask with the concentric pattern;
a second step of aligning the mask on a substrate coated with a photoresist and performing a light-exposing process;
a third step of developing the light-exposed substrate to obtain a concentric pattern formed of the photoresist, the photoresist of the concentric pattern being in the form of tori;
a fourth step of performing a reflow process for the developed substrate to allow the photoresist in the form of tori to be curved;
a fifth step of fabricating a stamper in which the concentric pattern formed of the photoresist in the form of tori is engraved in a depressed fashion; and
a sixth step of injection-molding a lens with the concentric pattern by using the stamper as a mold.

2. The method as claimed in claim 1, wherein the mask comprises a film mask or a chromium mask.

3. The method as claimed in claim 1, wherein the fifth step comprises the steps of:
coating a metallic thin film on the substrate;
electroplating the metallic thin film with nickel and separating a nickel-plated portion from the substrate; and
using the nickel-plated portion as the stamper.

4. The method as claimed in claim 3, wherein in the fifth step, the coating of the metallic thin film comprises chromium coating.

5. The method as claimed in claim 4, wherein in the fifth step, gold is further coated after coating the chromium.

6. The method as claimed in claim 1, wherein the respective tori constituting the concentric pattern in the mask have different thicknesses from one another.

7. The method as claimed in claim 1, wherein concentric circles on the lens injection-molded in the sixth step are formed to have desired spacing between them.

8. The method as claimed in claim 1, wherein concentric circles on the lens injection-molded in the sixth step are formed such that neighboring tori are in contact with each other.

9. A method of manufacturing a mild-layered microlens, the method comprising:
a first step of aligning a first mask on a substrate coated with a photoresist and performing a light-exposing process, the first mask including a circular light-shielding region through which light cannot be transmitted;
a second step of developing the light-exposed substrate to obtain a cylindrical photoresist portion;
a third step of performing a reflow process for the developed substrate to change the photoresist portion into a spherical lens feature;
a fourth step of fabricating a first stamper in which the spherical lens feature is engraved in a depressed fashion;
a fifth step of fabricating a second stamper in which the spherical lens feature is formed in a raised fashion, by using the first stamper;
a sixth step of aligning a second mask on the second stamper coated with a photoresist and performing a light-exposing process, the second mask including a light-shield region smaller than the circular light-shielding region formed in the first mask;
a seventh step of developing the photoresist formed on the spherical lens of the second stamper through the light exposure and performing a reflow process;
an eighth step of fabricating a third stamp in which a double-layered structure composed of the photoresist formed on the spherical lens is engraved in a depressed fashion; and
a ninth step of injection-molding a lens by using the third stamper as a mold so that the double-layered structure composed of the photoresist formed on the spherical lens is formed thereon in a raised fashion.

10. The method as claimed in claim 9, wherein the first mask comprises a film mask or a chromium mask.

11. The method as claimed in claim 9, wherein a plurality of shielding regions are arrayed on the first mask.

12. The method as claimed in claim 10, wherein the second mask comprises a chromium mask.

13. The method as claimed in claim 9, wherein the fourth, fifth and eighth steps comprise the steps of:
coating a metallic thin film;
electroplating the metallic thin film with nickel and separating only a nickel-plated portion; and
using the nickel-plated portion as the stamper.

14. The method as claimed in claim 13, wherein the coating of the metallic thin film comprises chromium coating.

15. The method as claimed in claim 14, wherein the coating of the metallic film further comprises additional coating of gold after the chromium coating.

16. A method of manufacturing a microlens with a grating formed thereon, the method comprising:
a first step of aligning a first mask on a substrate coated with a photoresist and performing a light-exposing process, the first mask including a circular light-shielding region through which light cannot be transmitted;
a second step of developing the light-exposed substrate to obtain a cylindrical photoresist portion;
a third step of performing a reflow process for the developed substrate to change the photoresist into a spherical lens feature;
a fourth step of fabricating a first stamper in which the spherical lens feature is engraved in a depressed fashion;
a fifth step of fabricating a second stamper made of a transparent plastic material, the second stamper being formed with the spherical lens feature in a raised fashion by using the first stamper as a mold;
a sixth step of coating a grating material on the second stamper and coating the grating material with a photoresist;
a seventh step of aligning a second mask on the second stamper coated with the photoresist and performing a light-exposing process, the second mask including a light-shield region smaller than the light-shielding region formed on the first mask, the light-shield region having a grating feature; and
an eighth step of developing the photoresist formed on the spherical lens of the second stamper through the light exposure and etching the thin film, thereby forming the grating feature on the spherical lens.

17. The method as claimed in claim 16, wherein the first mask comprises a film mask or a chromium mask.

18. The method as claimed in claim 16, wherein the second mask comprises a chromium mask.

19. The method as claimed in claim 16, wherein the grating material comprises a metal.

20. The method as claimed in claim 16, wherein the grating material comprises an oxide.

21. The method as claimed in claim 16, wherein the grating feature is formed in a raised and depressed fashion.

22. The method as claimed in claim 16, wherein the fourth step comprises the steps of:
coating a metallic thin film;
electroplating the metallic thin film with nickel and separating only a nickel-plated portion; and
using the nickel-plated portion as the stamper.

23. The method as claimed in claim 22, wherein the coating of the metallic thin film comprises chromium coating.

24. The method as claimed in claim 23, wherein the coating of the metallic thin film further comprises additional coating of gold after the chromium coating.
